(19) United States
(12) Patent Application Publication
(10) Pub. No.: US 2020/0373448 A1
(43) Pub. Date: Nov. 26, 2020

(54) SOLAR CELL HAVING EDGE COLLECTING ELECTRODE, AND SOLAR CELL MODULE COMPRISING SAME

(71) Applicant: Hyundai Energy Solutions Co., Ltd., Seongnam-si, Gyeonggi-do (KR)

(72) Inventors: Do Hyeon Kyeong, Seongnam-si (KR); Hoon Oh, Seongnam-si (KR); Tae Jun Kim, Seongnam-si (KR); Hyun Shin Kang, Seongnam-si (KR); Hee Jin Maeng, Seongnam-si (KR); Min Su Lee, Seongnam-si (KR)

(73) Assignee: Hyundai Energy Solutions Co., Ltd., Seongnam-si, Gyeonggi-do (KR)

(21) Appl. No.: 16/758,733

(22) PCT Filed: Oct. 25, 2017
(86) PCT No.: PCT/KR2017/011823

§ 371 Date: Apr. 23, 2020

(51) Int. Cl. H01L 31/05; H01L 31/02; H01L 31/0224

(52) U.S. Cl. CPC H01L 31/0508; H01L 31/022425; H01L 31/0201

(57) ABSTRACT

The present invention relates to a solar cell having an edge collecting electrode comprising a semiconductor substrate having the main region and the edge region; a plurality of finger electrodes provided on the front surface and/or the rear surface of the substrate and arranged in the main region so as to be spaced apart in parallel; and a plurality of edge collecting electrodes provided in the edge region, wherein the edge region is provided at one end side or both end sides of the substrate, and an arrangement direction of the plurality of finger electrodes differs from an arrangement direction of the plurality of edge collecting electrodes, and a solar cell module comprising the same.

### FIELD OF THE INVENTION

The technology disclosed in this specification relates to a solar cell having an edge collecting electrode and a solar cell module including the same, and more specifically, to a solar cell having an edge collecting electrode, which prevents a cell crack phenomenon by an interconnector and improves the adhesion characteristics of the interconnector by dividing a planar region of the solar cell into a main region and an edge region and positioning an outermost contact point of the interconnector at or near a boundary between the main region and the edge region, and improves the carrier collecting efficiency by placing an edge collecting electrode physically separated from the interconnector in the edge region, and a solar cell module including the same.

### BACKGROUND ART

A solar cell module is a device that receives solar light and performs photoelectric transformation thereto, and includes a plurality of solar cells. Each solar cell of the solar cell module may be referred to as a p-n junction diode.

The process of transforming solar light into electricity by the solar cell, so-called a photoelectric transformation process, is as follows. If solar light is input to a p-n junction of the solar cell, electron-hole pairs are generated, and electrons are transferred to an n-type semiconductor layer and holes are transferred to a p-type semiconductor layer by an electric field, thereby generating a photovoltaic power between the p-n junctions. In this state, if a load or system is connected to both ends of the solar cell, a current flows to produce electricity. A front electrode and a back electrode for collecting electrons and holes are respectively provided to a front surface and a rear surface of the solar cell.

Meanwhile, the plurality of solar cells of the solar cell module are electrically connected to each other. For example, a front electrode 111 of a first solar cell 110 is connected to a back electrode 122 of a neighboring second solar cell 120. The conductor that electrically connects the front electrode 111 of the first solar cell 110 and the back electrode 122 of the second solar cell 120 is generally referred to as an interconnector 130 (see FIG. 1).

The interconnector that electrically connects neighboring solar cells is made of a conductor with a certain width and thickness, and a common interconnector is also referred to as a ribbon since it is shaped like a ribbon to connect the neighboring solar cells.

The ribbon-type interconnector (hereinafter, referred to as a ribbon interconnector) has a predetermined width and thickness as described above, for example a width of about 1.5 mm and a thickness of about 270 μm, so that a certain area of the solar cell is inevitably covered by the interconnector. Since the solar cell is a device that receives solar light and transforms it into electricity, if the light receiving area of the solar cell is reduced, it means a decrease in photoelectric transformation efficiency.

In order to solve the reduction of the light receiving area by the interconnector and to improve the efficiency of the solar cell, the research for replacing the ribbon interconnector with a wire-type interconnector (hereinafter, referred to as a wire interconnector) are being actively conducted. The wire interconnector method is a method of connecting electrodes of neighboring solar cells using a conductive wire having a diameter of about 200 to 600 μm.

The wire interconnector method may minimize the reduction of the light receiving area by the interconnector since the width (diameter) of the conductor is significantly smaller than the ribbon interconnector method. Also, since the reduction of the light receiving area by the interconnector is small, a larger number of interconnectors may be disposed in the solar cell in comparison to the ribbon interconnector method, thereby improving the efficiency of the solar cell.

Meanwhile, in connecting the front electrode on the front surface of the first solar cell and the back electrode on the rear surface of the second solar cell, the interconnector is bent between the first solar cell and the second solar cell in both the ribbon interconnector method and the wire interconnector method. However, in the bent region, the first solar cell and the second solar cell that come into contact with the interconnector may have a high possibility of micro cracks caused by the interconnector. In the EL (Electroluminescence) image of FIG. 5, it may be found that cracks (dotted display parts) are generated at edges of the solar cell. Also, it should be noted that the adhesion between the interconnector and the electrode is weakened due to bending.

In both the ribbon interconnector method and the wire interconnector method, the cell cracking phenomenon and the weakening of the adhesive force with the outermost electrode as described above may occur. However, since the wire interconnector method has more interconnectors than the ribbon interconnector method, the above problems may occur more frequently in the wire interconnector method.

### RELATED PATENT LITERATURE

### Korean Patent No. 1138174

### SUMMARY OF THE INVENTION

This present invention is directed to providing a solar cell having an edge collecting electrode, which may prevent a cell crack phenomenon by an interconnector and improve the adhesion characteristics of the interconnector by dividing a planar region of the solar cell into a main region and an edge region and positioning an outermost contact point of the interconnector at or near a boundary between the main region and the edge region, and improve the carrier collecting efficiency by placing an edge collecting electrode physically separated from the interconnector in the edge region, and a solar cell module including the same.

In one general aspect, there is provided a solar cell having an edge collecting electrode, comprising: a semiconductor substrate having a main region and an edge region; a plurality of finger electrodes provided on any one of a front surface and a rear surface of the substrate and arranged in the main region so as to be spaced apart in parallel; and a plurality of edge collecting electrodes provided in the edge region, wherein the edge region is provided at one end side or both end sides of the substrate, an arrangement direction of the plurality of edge collecting electrodes differs from an arrangement direction of the plurality of finger electrodes, and the plurality of edge collecting electrodes are connected to at least one finger electrode selected from the plurality of finger electrodes.

In another aspect, there is provided a solar cell module having an edge collecting electrode, comprising: a first solar cell and a second solar cell arranged adjacent to each other; and an interconnector configured to electrically connect the first solar cell and the second solar cell, wherein the first solar cell or second solar cell includes: a semiconductor substrate having a main region and an edge region; a plurality of finger electrodes provided to any one of a front surface and a rear surface of the substrate and arranged in the main region so as to be spaced apart in parallel; and a plurality of edge collecting electrodes provided in the edge region, wherein the edge region is provided at one end side or both end sides of the substrate, an arrangement direction of the plurality of edge collecting electrodes differs from an arrangement direction of the plurality of finger electrodes, and the plurality of edge collecting electrodes are connected to at least one finger electrode selected from the plurality of finger electrodes.

The solar cell having an edge collecting electrode and the solar cell module including the same as disclosed in this specification provide the following advantages.

Since the outermost contact point of the interconnector is located at an inner side of the substrate as much as the edge region from the edge of the substrate, it is possible to prevent cracking by the interconnector and improve the adhesion of the interconnector.

In addition, since the edge collecting electrode disposed in a direction crossing the finger electrode in the main region is provided in the edge region, it is possible to guide the arrangement of the interconnector and improve the carrier collection efficiency.

### BRIEF DESCRIPTION OF THE DRAWINGS

FIG. 1 is a diagram showing a general solar cell module.

FIG. 2 is a plan view showing a solar cell having an edge collecting electrode according to the first embodiment disclosed in this specification.

FIGS. 3A and 3B are reference views showing an arrangement form of the edge collecting electrodes according to the second embodiment disclosed in this specification.

FIG. 4 is a perspective view showing a solar cell module according to the first embodiment disclosed in this specification.

FIG. 5 is an EL image showing that cracks occurs at edge portions of the solar cell.

### DETAILED DESCRIPTION OF THE PREFERRED EMBODIMENTS

In describing the embodiments disclosed in this specification, if it is determined that a detailed description of related known configurations or functions may obscure the gist of this specification, the detailed description may be omitted.

It should be noted that technical terms used in this specification are only used to describe specific embodiments and are not intended to limit the scope of the technology disclosed in this specification. In addition, the technical terms used in this specification should be interpreted as meanings generally understood by those of ordinary skill in the field to which the technology disclosed in this specification belongs, unless otherwise defined in this specification, and they should not be interpreted as a comprehensive meaning or an excessively reduced meaning. In addition, when any technical term used in this specification is an incorrect technical term that does not accurately represent the idea of the technology disclosed in this specification, it should be understood as being replaced by a technical term that can be correctly understood by those skilled in the art. In addition, general terms used in this specification should be interpreted as defined in the dictionary or according to the context before and after, and should not be interpreted as an excessively reduced meaning.

The expressions “include,” “may include,” and the like used in this specification indicate the existence of a corresponding function, operation or component disclosed therein, and do not limit one or more additional functions, operations or components. Also, in this specification, the terms “configured”, “include” or “have” are intended to indicate the presence of features, numbers, steps, actions, components, parts, or combinations thereof described in the specification, and should not be understood to exclude the presence or possibility of addition of one or more other features, numbers, steps, actions, components, parts, or combinations thereof in advance. In other words, the terms should not be construed to essentially include all of various components or various steps described in the specification, and it should be interpreted that some of those components or steps may not be included or additional components or steps may be further included.

In addition, the terms “module” and “unit” used in the terms of components disclosed in this specification are given or mixed only considering the ease of writing the specification, and do not have distinct meanings or roles in themselves.

Also, terms including ordinal numbers such as “first” and “second” used in this specification may be used to describe various components, but the components should not be limited by the terms. The terms are only used to distinguish one component from another. For example, a first component may be referred to as a second component without departing from the scope of the present disclosure, and similarly, the second component may also be referred to as the first component.

Hereinafter, embodiments disclosed in this specification will be described in detail with reference to the accompanying drawings, but the same or similar elements will be designated by the same reference numbers regardless of reference numerals, and redundant descriptions thereof will be omitted.

In addition, in describing the technology disclosed in this specification, when it is determined that a detailed description of related known technologies may obscure the gist of the technology disclosed in this specification, the detailed description will be omitted. In addition, it should be noted that the accompanying drawings are only for facilitating understanding of the scope of the technology disclosed in this specification, and should not be interpreted as limiting the scope of the technology by the accompanying drawings.

Description of a General Interconnector

An interconnector may mean a conductor that connects electrodes of neighboring solar cells, for example an electrode on a front surface of a first solar cell and an electrode on a rear surface of the second solar cell.

The interconnector may be classified into a ribbon interconnector and a wire interconnector depending on the geometric shape. The ribbon interconnector may have a ribbon shape with a certain width and thickness, and the wire interconnector may have a circular wire shape with a constant diameter or a wire shape with different widths and thicknesses.

In connecting electrodes of neighboring solar cells, the interconnector is bent in the space between a solar cell and a solar cell. Due to the bending of the interconnector, a crack may occur at an end of the solar cell that contacts the bending point of the interconnector, or the interconnector may be attached to the bus bar and detached therefrom at the end of the solar cell. Such defects may more frequently occur in the wire interconnector method. This is because the number of interconnectors is larger in the wire interconnector method than in the ribbon interconnector method. The cell cracking phenomenon and the poor adhesion phenomenon caused by the bending of the interconnector are more serious as the length of the interconnector from an outermost pad on the front surface of the first solar cell to an outermost pad on the rear surface of the second solar cell is shorter and the thickness of the interconnector in the vertical direction is greater at the bending point of the interconnector. If the interconnector has a short length and a large thickness, a greater bending stress is generated at the bending point of the interconnector. The bending stress may be transmitted to the end of the solar cell in contact with the bending point of the interconnector, which may cause further cracking at the end of the solar cell and cause the interconnector to be attached and detached more easily at the end of the solar cell.

In order to solve this problem, it may be considered to reduce the thickness of the interconnector. However, if the thickness of the interconnector is reduced, the resistance applied to the interconnector is increased. As an alternative, it is possible to increase the length of the interconnector from the outermost pad on the front surface of the first solar cell to the outermost pad on the rear surface of the second solar cell. Specifically, it is a method of moving the outermost pads on the front and rear surfaces of the solar cell to an inner region of the solar cell.

Meanwhile, if the outermost contact point of the interconnector and the electrode moves away from an upper edge of the solar cell to the inner region of the solar cell, this means that there is no solar cell electrode between the outermost contact point and the upper edge of the solar cell. Through this, it is possible to solve the cell cracking phenomenon and the weakening of the adhesion, but there may be a problem that the carrier collection efficiency is deteriorated due to the absence of a solar cell electrode between the outermost contact point and the upper edge of the solar cell.

Edge Collecting Electrode

An edge collecting electrode disclosed in this specification may be applied to the solar cell, which may enhance the carrier collection efficiency while improving the cell cracking phenomenon by the interconnector and the weakening of the adhesion between the interconnector and the electrode as described above, and a solar cell module using the same.

Specifically, the technique disclosed in this specification solves the cell cracking phenomenon and the weakening of the adhesive force by moving the outermost contact point to the inner region of the solar cell, and also prevents deterioration of the solar cell efficiency such as the carrier collection efficiency by providing an edge collecting electrode in a region between the outermost contact point and the edge of the solar cell and disposing an interconnector between the edge collecting electrodes.

In addition, the interconnector applied to the solar cell or the solar cell module disclosed in this specification is not limited to the shape. A wire interconnector may be applied in a preferred configuration, but a ribbon interconnector may also be applied.

A solar cell according to the technology disclosed in this specification includes a semiconductor substrate having a main region and an edge region, a plurality of finger electrodes provided to at least one of a front surface and a rear surface of the substrate and arranged in the main region so as to be spaced apart in parallel, and a plurality of edge collecting electrodes provided in the edge region, wherein the edge region is provided at one end side or both end sides of the substrate, an arrangement direction of the plurality of edge collecting electrodes differs from an arrangement direction of the plurality of finger electrodes, and the plurality of edge collecting electrodes are connected to at least one finger electrode selected from the plurality of finger electrodes.

In addition, a solar cell module according to the technology disclosed in this specification includes a first solar cell and a second solar cell arranged adjacent to each other; and an interconnector configured to electrically connect the first solar cell and the second solar cell, wherein the first solar cell or second solar cell includes a semiconductor substrate having a main region and an edge region, a plurality of finger electrodes provided to any one of a front surface and a rear surface of the substrate and arranged in the main region so as to be spaced apart in parallel, and a plurality of edge collecting electrodes provided in the edge region, wherein the edge region is provided at one end side or both end sides of the substrate, an arrangement direction of the plurality of edge collecting electrodes differs from an arrangement direction of the plurality of finger electrodes, and the plurality of edge collecting electrodes are connected to at least one finger electrode selected from the plurality of finger electrodes.

In the solar cell or the solar cell module described above, the selected at least one finger electrode may be selected from three finger electrodes located at an outermost side of the main region.

In addition, the plurality of edge collecting electrodes may be arranged orthogonal to the plurality of finger electrodes.

In addition, the interconnector may be disposed between the edge collecting electrodes.

In addition, among the plurality of edge collecting electrodes, an edge collecting electrode located at an edge portion of the solar cell may have a different length from edge collecting electrodes located in other regions.

In addition, the solar cell or the solar cell module may further include a bus bar electrode, and in this case, the bus bar electrode may be arranged in a direction crossing the finger electrode and is connected to an interconnector that electrically connects neighboring solar cells.

In addition, the solar cell or the solar cell module may further include a plurality of conductive pads, and the plurality of conductive pads may be arranged in a direction crossing the finger electrode so as to be spaced apart from each other and connected to an interconnector that electrically connects neighboring solar cells.

In addition, the solar cell or the solar cell module may further include a bus bar electrode and a conductive pad, the bus bar electrode may be arranged in a direction crossing the finger electrode and connected to the finger electrode, and the plurality of conductive pads may be arranged in a direction crossing the finger electrode so as to be spaced apart from each other and connected to an interconnector that electrically connects neighboring solar cells.

In addition, the solar cell or the solar cell module may further include a bus bar electrode and a plurality of conductive pads, the plurality of conductive pads may be arranged so as to be spaced apart from each other on a finger electrode in a region where an interconnector for electrically connecting neighboring solar cells is disposed, and the bus bar electrode may be provided between the plurality of conductive pads.

The bus bar electrode and the conductive pad described above may be included in a bus electrode described later.

In addition, at least one of the plurality of edge collecting electrodes may be connected to a conductive pad located at an outermost side of the main region.

In addition, the interconnector may be a ribbon-type interconnector or a wire-type interconnector.

More specifically, the edge collecting electrode according to the technology disclosed in this specification will be described below.

First, the edge collecting electrode may be provided in the edge region of the semiconductor substrate. Alternatively, the edge collecting electrode may be provided at one end side or both end sides of a semiconductor substrate (or, a substrate).

The semiconductor substrate is divided into an edge region and a main region. The edge region may mean an end portion (or, an edge portion) of a solar cell (or, a semiconductor substrate) provided to one side or both sides of the main region.

In another sense, the main region may mean a region in which the plurality of finger electrodes are located, and the edge region may mean a region in which the edge collecting electrode is located. Alternatively, the edge region may mean one end portion or both end portions (or, edge portions) of a solar cell (or, a semiconductor substrate) in which the plurality of finger electrodes are not located.

In still another sense, the main region means a region in which a bus electrode (or, a bus bar, a bus bar electrode) is located, and the edge region is an end portion (or, an edge portion) of a solar cell (or, a semiconductor substrate) provided to one side or both sides of the main region. Alternatively, the edge region may mean one end portion or both end portions (or, edge portions) of a solar cell (or, a semiconductor substrate) in which the bus electrode is not located.

Here, the bus electrode may serve to collect charges through at least one of the plurality of finger electrodes and the edge collecting electrode.

In addition, the bus electrode may be disposed in a direction crossing the finger electrode and connected to an interconnector that electrically connects neighboring solar cells.

The term ‘direction crossing’ a specific electrode or ‘crossing direction’ used in this specification may generally mean a direction orthogonal to the specific electrode, but it mean a direction arranged not in parallel but at an angle such as a diagonal direction to the extent that the technology disclosed in this specification can be applied.

The bus electrode according to an embodiment disclosed in this specification may include at least one of a bus bar electrode formed by successively disposing electrodes in a direction crossing the finger electrode and a plurality of conductive pads arranged so as to be spaced apart in a direction crossing the finger electrode.

The edge collecting electrode according to the technology disclosed in this specification may be basically located in the edge region to collect electric charges.

In addition, a plurality of edge collecting electrodes are spaced apart from each other and located in the edge region. Here, the interconnector may be disposed between the arranged edge collecting electrodes to prevent the cell crack phenomenon by the interconnector and improve the adhesive properties of the interconnector.

In another sense, the arrangement direction of the edge collecting electrodes may differs from the arrangement direction of the finger electrodes to provide a space in which the interconnector is disposed. For example, the arrangement direction of the edge collecting electrodes may be an orthogonal direction crossing the finger electrode or an inclined direction such as a diagonal line within a range that can provide a space in which the interconnector is disposed.

As described above, the interconnector may be disposed between the edge collecting electrodes. Therefore, an intermediate electrode capable of transferring electric charges collected from the edge collecting electrode to the interconnector may be required. This is because the edge collecting electrode and the interconnector do not physically directly contact due to the nature of the arrangement direction, so an electrode that transfers charges therebetween is required.

According to the technique disclosed in this specification, the finger electrode located in the main region may act as the intermediate electrode. Therefore, in this case, the edge collecting electrode may be connected to at least one finger electrode selected from the plurality of finger electrodes located in the main region.

Hereinafter, the edge collecting electrode according to the first embodiment and the second embodiment disclosed in this specification will be described in detail with reference to the drawings.

### First Embodiment—Edge Collecting Electrode Connected to the Outermost Finger Electrode

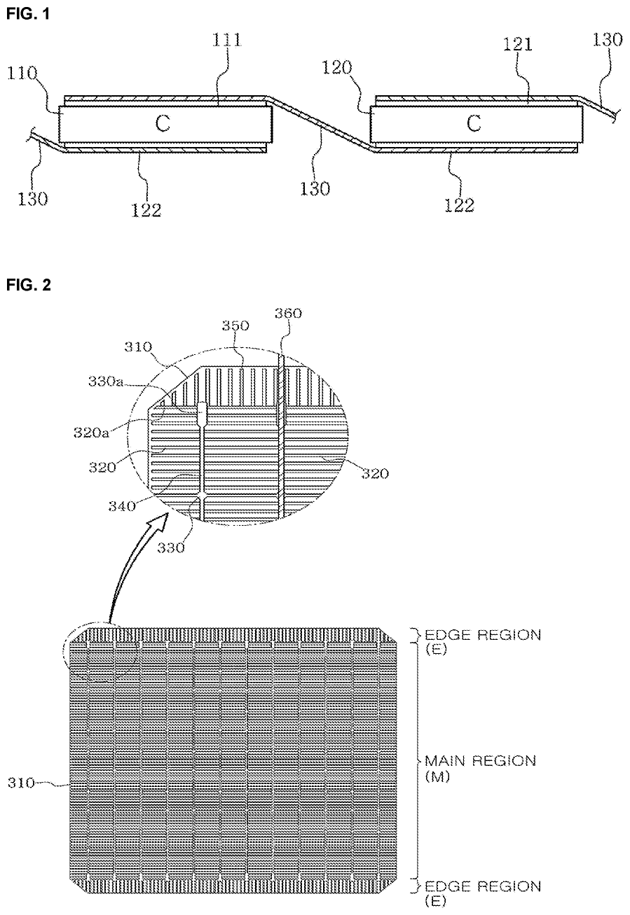

Hereinafter, a solar cell having an edge collecting electrode according to the first embodiment disclosed in this specification will be described with reference to FIG. 2.

Specifically, the first embodiment disclosed in this specification represents a case in which the selected at least one finger electrode connected to the edge collecting electrode is an outermost finger electrode in the main region.

Referring to FIG. 2, the solar cell 10 having an edge collecting electrode according to the first embodiment includes a semiconductor substrate 310 having a p-n junction. Finger electrodes 320 are provided to a front surface and a rear surface of the substrate 310, respectively. The finger electrode 320 provided to the front surface of the substrate 310 collects electrons generated by photoelectric transformation, and the finger electrode (not shown) provided to the rear surface of the substrate 310 collects holes generated by photoelectric transformation, or vice versa. The solar cell is classified into a front electrode type, a back electrode type, or the like depending on the arrangement of electrodes, and is classified into a front surface light receiving type, a double-sided light receiving type, or the like depending on the solar light receiving type. The solar cell applied to the technology disclosed in this specification is not limited in shape as long as it has a p-n junction that enable photoelectric transformation. In addition, a divided cell in which a typical solar cell is divided into a plurality of cells may also be applied to the solar cell or the solar cell module according to the technology disclosed in this specification. The term “divided cell” disclosed in this specification refers to that a solar cell (hereinafter, referred to as a “unit cell”) is divided into a plurality of parts. A normal solar cell, namely a normal unit cell, refers to a solar cell in which a p-n junction structure and an electrode structure are completed by applying a solar cell process to a silicon substrate having a width and length of 6 inches (about 156 mm×156 mm), and the ‘divided cell’ of the present disclosure refers to a cell in which the unit cell is divided into a plurality of equal parts. The unit cell may use a silicon substrate of 5 to 8 inches in length and width, besides the silicon substrate of 6 inches in width and length. Also, the “divided cell” may mean a solar cell having an area corresponding to the divided cell obtained from the unit cell described above. In this case, the ‘divided cell’ means a solar cell completed by applying a solar cell process onto a silicon substrate having an area corresponding to the divided cell obtained from the unit cell.

Since the ‘divided cell’ is obtained by dividing a cell in which the solar cell manufacturing process is completed, the divided cell has a p-n junction structure and an electrode structure in a completed form, like the unit cell.

In addition, the divided cell in which a typical solar cell is divided into a plurality of parts may also be applied to the solar cell or the solar cell module according to the technology disclosed in this specification.

For reference, if a front surface light-receiving solar cell is configured, the finger electrode provided to the rear surface of the substrate may have a plate shape like an Al electrode that induces formation of a rear surface field. For convenience of description, the following description will be based on the solar cell 10 in which the same type of finger electrode 320 is provided to the front surface and the rear surface of the substrate 310.

A plurality of finger electrodes 320 are provided to the front surface or the rear surface of the substrate 310, and the plurality of finger electrodes 320 are arranged to be spaced apart in parallel.

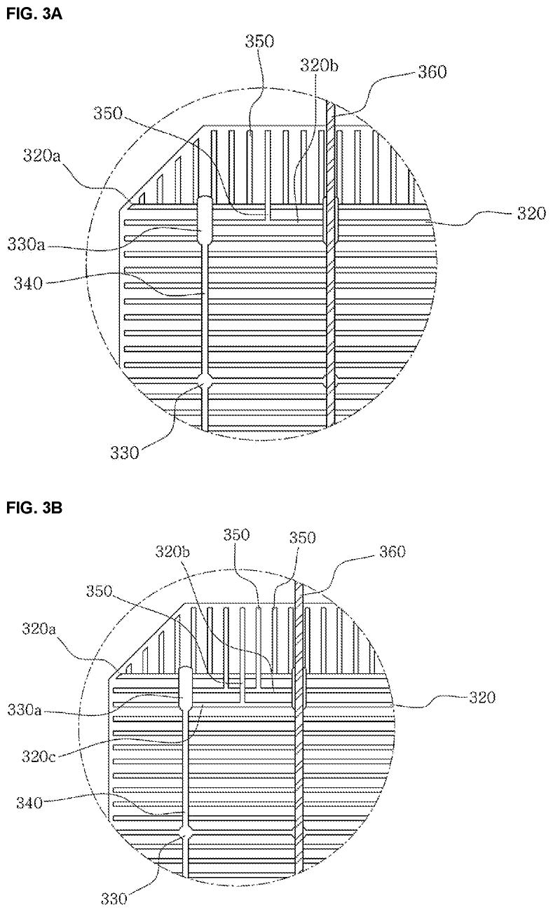

In addition, on the substrate 310, a plurality of conductive pads 330 may be spaced apart in a direction crossing the finger electrode 320 (an orthogonal direction in FIG. 2). Each conductive pad 330 is connected to the finger electrode 320 at the provided position, and the arrangement direction of the columns formed by the plurality of conductive pads 330 may be the same as the direction in which the interconnector 360 (see FIG. 3) described later is disposed.

The interconnector 360 is disposed on the conductive pad 330, and the arrangement direction of the interconnectors 360 may be the same as the arrangement direction of the columns formed by the plurality of conductive pads 330, or a direction crossing the arrangement direction of the finger electrodes 320 (an orthogonal direction in FIG. 2).

The conductive pad 330 may serve to transfer electrons or holes collected by the finger electrode 320 to the interconnector 360, and the interconnector 360 may serve to receive carriers collected by the finger electrode 320 through the conductive pad 330 and transmit the carriers to an external system or power storage device.

Meanwhile, in another embodiment, a bus bar electrode 340 may be further provided. In this case, the bus bar electrode 340 is provided in a direction crossing the plurality of finger electrodes 320 (an orthogonal direction in FIG. 2), and the conductive pad 330 is provided on the bus bar electrode 340 at a point where the bus bar electrode 340 and the finger electrode 320 intersect. In another embodiment, by providing the bus bar electrode 340 between the conductive pad 330 and the conductive pad 330, it is also possible to have a structure in which the finger electrode 320 and the bus bar electrode 340 are connected to the conductive pad 330.

In the above embodiment, the interconnector 360 may be connected to at least one of the conductive pad 330 and the bus bar electrode 340.

At least one of the conductive pad 330 and the bus bar electrode 340 may mean the bus electrode described above.

In the above embodiment, the case where each of the front electrode and the back electrode of the solar cell is a combination of a finger electrode and a conductive pad or a combination of a finger electrode, a bus bar electrode and a conductive pad has been described, but as another embodiment, the conductive pad may be omitted. If the conductive pad is omitted, each of the front electrode and the back electrode of the solar cell may be configured with only a finger electrode or a combination of a finger electrode and a bus bar electrode. When only a finger electrode is used, the interconnector may be connected orthogonal to the plurality of finger electrodes. In addition, if a combination of a finger electrode and a bus bar electrode is used, the bus bar electrode may be arranged in an orthogonal form on the plurality of finger electrodes, and the interconnector may be electrically connected to the bus bar electrode.

The structures of the finger electrode 320, the conductive pad 330 and the interconnector 360 have been described above. Meanwhile, the semiconductor substrate 310 is divided into a ‘main region M’ and an ‘edge region E’ based on a plane.

Here, the main region M and the edge region E are as described above, and as an additional meaning, the ‘main region M’ may mean a region provided with a coupling structure of the finger electrode 320, the conductive pad 330 and the interconnector 360, the ‘edge region E’ may mean an edge portion of the solar cell provided to one side or both sides of the main region M. Here, the edge collecting electrode 350 may be provided in the edge region E.

As described above, the plurality of finger electrodes 320 are arranged in the main region M so as to be spaced apart in parallel, and each of the plurality of edge collecting electrodes 350 may be connected to a selected finger electrode among the plurality of finger electrodes 320 located in the main region M.

The first embodiment shows the case where the selected finger electrode 320a is a finger electrode 320a provided at an outermost position of the main region M (see FIG. 2).

The region where the plurality of edge collecting electrodes 350 are provided may be referred to the edge region E as described above.

The plurality of edge collecting electrodes 350 connected to the outermost finger electrode 320a and provided in the edge region E basically serve to collect carriers generated by photoelectric transformation, like the finger electrode 320. In addition, the interconnector 360 may be provided to a region between the edge collecting electrode 350 and the edge collecting electrode 350.

The solar cell according to the first embodiment may be configured with a finger electrode 320 provided in the main region M and a plurality of edge collecting electrodes 350 provided in the edge region E and connected to the outermost finger electrode 320a among the plurality of finger electrodes 320 located in the main region M.

Similar to the finger electrode 320 of the main region M that is connected to the conductive pad 330, the outermost finger electrode 320a is also connected to a conductive pad 330 (hereinafter, referred to as outermost conductive pad 330a), and the interconnector 360 may be connected on the outermost conductive pad 330a.

Since the outermost conductive pad 330a is a conductive pad 330 disposed at the outermost side of the main region M, the contact point of the outermost conductive pad 330a and the interconnector 360 may be referred to as a last contact point made by the conductive pad 330 and the interconnector 360 on the substrate 310, and hereinafter, this contact pad may be called an outermost contact point.

Meanwhile, as described above, a structure in which the conductive pad 330 is omitted is also possible, and in this case, the outermost contact point may mean a contact point between the interconnector and the outermost collecting electrode or a contact point between the interconnector and the outermost bus bar electrode.

By using the configuration in which the outermost contact point is moved to the inner region of the substrate 310 as much as the distance of the edge region E as described above, it is possible to prevent cracking and improve the coupling force of the interconnector 360 as described above.

In addition, since the plurality of edge collecting electrodes 350 are provided in the edge region E and the plurality of edge collecting electrodes 350 form a structure connected to the outermost collecting electrode 320a, it is possible to prevent the carrier collection efficiency in the edge region E from deteriorating.

### Second Embodiment—Edge Collecting Electrode Connected to at Least One Finger Electrode Selected from Three Finger Electrodes at the Outermost Side

Hereinafter, a solar cell having an edge collecting electrode according to the second embodiment disclosed in this specification will be described with reference to FIGS. 3A and 3B.

Specifically, the second embodiment disclosed in this specification shows a case where the edge collecting electrode is connected to at least one finger electrode selected from three outermost finger electrodes.

The structure of the edge collecting electrode 350 according to the second embodiment is as follows.

Referring to FIGS. 3A and 3B, the plurality of edge collecting electrodes 350 may be connected to at least one finger electrode 320a, 320b, 320c selected from the plurality of finger electrodes 320 in the main region M.

That is, the selected at least one finger electrode 320a may be at least one of the three outermost finger electrodes in the main region E.

The plurality of edge collecting electrodes 350 may be repeatedly arranged so as to be spaced apart, and the interconnector 360 may be disposed between the edge collecting electrode 350 and the edge collecting electrode 350 not to contact the edge collecting electrodes 350.

FIG. 3A shows the case where the selected finger electrode includes finger electrodes from the finger electrode at the outermost side of the main region M to the second finger electrode 320b, and FIG. 3B shows the case where the selected finger electrode includes finger electrodes from the finger electrode at the outermost side of the main region M to the third finger electrode 320c.

The plurality of edge collecting electrodes 350 may be provided in a direction orthogonal to the finger electrode 320 of the main region M, but the plurality of edge collecting electrodes 350 may also be arranged along a diagonal line or the like on the premise that a space in which the interconnector 360 is disposed is provided between the edge collecting electrodes 350.

In summary, the edge collecting electrode 350 according to the technology disclosed in this specification is characterized in that the edge collecting electrode 350 1) is located in the edge region E, 2) is connected to a selected finger electrode 320a among the plurality of finger electrodes 320 located in the main region M, and 3) has an arrangement direction different from the arrangement direction of the finger electrodes 320. Due to this configuration, the interconnector 360 may be disposed between the edge collecting electrodes 350, thereby preventing cell cracking and improving the adhesive properties of the interconnector without deteriorating the carrier collection efficiency. In addition, when optimizing the width and thickness of the edge collecting electrode 350, the number of edge collecting electrodes 350 disposed in the edge region E and the spacing between the edge collecting electrodes 350, the carrier collection efficiency may be further improved.

Solar Cell Module

The solar cell having an edge collecting electrode according to the embodiments disclosed in the specification has been described above. Next, a solar cell module including the solar cell having an edge collecting electrode according to the technology disclosed in this specification will be described.

The solar cell module according to the technology disclosed in this specification includes a first solar cell and a second solar cell arranged adjacent to each other; and an interconnector configured to electrically connect the first solar cell and the second solar cell, wherein the first solar cell or second solar cell includes a semiconductor substrate having a main region and an edge region, a plurality of finger electrodes provided to any one of a front surface and a rear surface of the substrate and arranged in the main region so as to be spaced apart in parallel, and a plurality of edge collecting electrodes provided in the edge region, wherein the edge region is provided at one end side or both end sides of the substrate, an arrangement direction of the plurality of edge collecting electrodes differs from an arrangement direction of the plurality of finger electrodes, and the plurality of edge collecting electrodes are connected to at least one finger electrode selected from the plurality of finger electrodes.

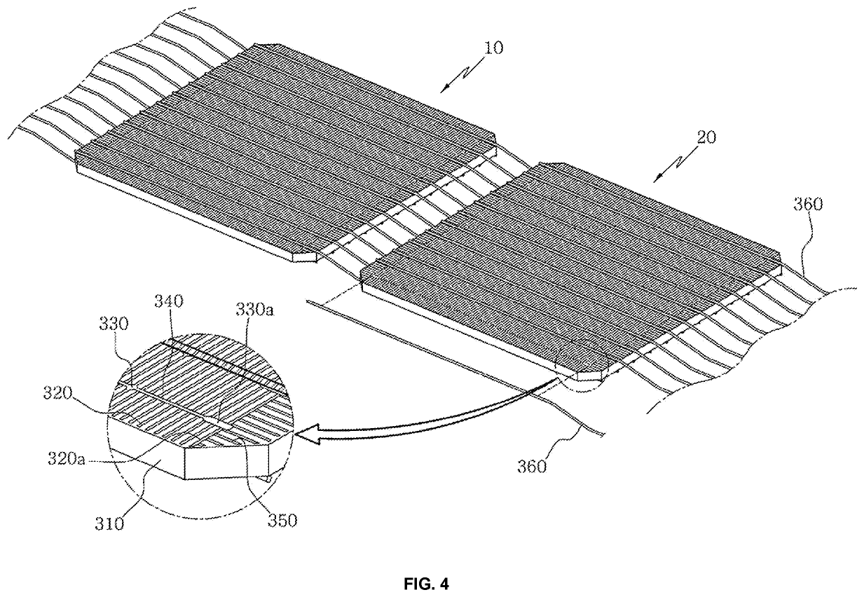

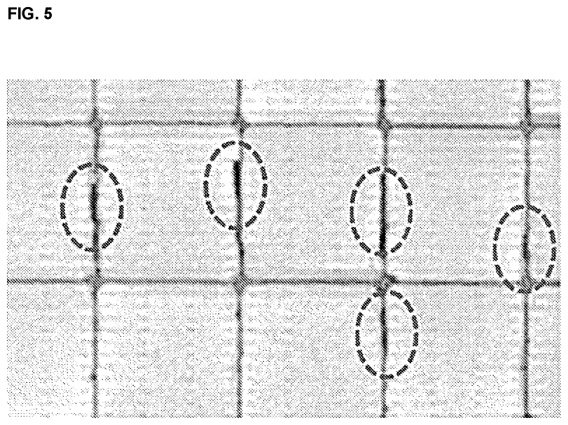

Referring to FIG. 4, the solar cell module according to the technology disclosed in this specification may include a plurality of solar cells. For example, the solar cell module may be configured to include a first solar cell 10 and a second solar cell 20 disposed adjacent to each other.

FIG. 4 shows the case where the selected at least one finger electrode is the outermost finger line 320a in the main region as in the first embodiment. However, as in the second embodiment, the selected at least one finger electrode may also be selected among the three outermost finger lines in the main region.

Each of the solar cells 10, 20 may have a structure of the solar cell having an edge collecting electrode 350 according to the technology disclosed in this specification as described above.

The plurality of solar cells 10, 20 may be electrically connected by the interconnector 360.

Specifically, the interconnector 360 may electrically connect the electrode on the front surface of the first solar cell 10 and the electrode on the rear surface of the second solar cell 20, and the interconnector 360 may be bent from the upper edge of the first solar cell 10 toward the lower edge of the second solar cell 20.

Meanwhile, the interconnector applied to the solar cell module according to the technology disclosed in this specification is not limited to its shape. As a preferred embodiment, a wire interconnector may be applied, but a ribbon interconnector may also be applied.

The electrode on the front surface of the first solar cell 10 and the electrode on the rear surface of the second solar cell 20 may include a plurality of finger electrodes arranged so as to be spaced apart in parallel.

In addition, the electrode on the front surface of the first solar cell 10 and the electrode on the rear surface of the second solar cell 20 may include only a plurality of finger electrodes, a combination of a plurality of finger electrodes and a conductive pad, a combination of a plurality of finger electrodes and a bus bar electrode, or a combination of a plurality of finger electrodes, a bus bar electrode and a conductive pad.

If the electrode on the front surface of the first solar cell 10 and the electrode on the rear surface of the second solar cell 20 include only finger electrodes, the interconnector is connected orthogonal to the plurality of finger electrodes. If the electrode on the front surface of the first solar cell 10 and the electrode on the rear surface of the second solar cell 20 include a combination of finger electrodes and a conductive pad, the conductive pad may be provided on the finger electrode in the region where the interconnector is disposed, and the plurality of conductive pads may be electrically connected to the interconnector. In this case, it is preferable that the conductive pad is provided on each finger electrode. If the electrode on the front surface of the first solar cell 10 and the electrode on the rear surface of the second solar cell 20 include a combination of finger electrodes and a bus bar electrode, the bus bar electrode may be arranged in an orthogonal shape on the plurality of finger electrodes, and the bus bar electrodes may be electrically connected to the interconnector.

If the electrode on the front surface of the first solar cell 10 and the electrode on the rear surface of the second solar cell 20 include a combination of finger electrodes, a bus bar electrode and a conductive pad, the bus bar electrode may be arranged to cross the plurality of finger electrodes, and the conductive pad may be provided on the bus bar electrode at the point where the bus bar electrode and finger electrode intersect. Along with this, the conductive pad may be provided on the finger electrode in the region where the interconnector is disposed, and the bus bar electrode may be provided between the conductive pad and the conductive pad. If the conductive pad is provided, the interconnector may be connected to the conductive pad.

Meanwhile, the edge region E having the edge collecting electrode 350 may be provided to the front surface of the first solar cell 10 and the rear surface of the second solar cell 20, respectively. In addition, on the front surface of the first solar cell, the interconnector 360 may form an outermost contact point with the outermost conductive pad 330a, and the interconnector 360 forming the outermost contact point may be disposed between the edge collecting electrodes 350 in the edge region E and extend toward the edge of the first solar cell.

On the rear surface of the second solar cell, the interconnector 360 also forms an outermost contact point with the outermost conductive pad 330a, and the interconnector 360 forming the outermost contact point may be disposed between the edge collecting electrodes 350 in the edge region E and extend toward the edge of the second solar cell.

Here, the conductive pad 330 may be omitted as described above, and in this case, the outermost contact point means a contact point between the interconnector and the outermost finger electrode or a contact point between the interconnector and the outermost bus bar electrode.

### REFERENCE NUMBERS

10: first solar cell
20: second solar cell
310: semiconductor substrate
320: finger electrode
320a: outermost finger electrode
320b: second finger electrode from the outermost side
320c: third finger electrode from the outermost side
330: conductive pad
330a: outermost conductive pad
340: bus bar electrode
350: edge collecting electrode
360: interconnector
M: main region
A: edge region

### INDUSTRIAL APPLICABILITY

Since the outermost contact point of the interconnector is located at an inner side of the substrate as much as the edge region from the edge of the substrate, it is possible to prevent cracking by the interconnector and improve the adhesion of the interconnector.

In addition, since the edge collecting electrode disposed in a direction crossing the finger electrode in the main region is provided in the edge region, it is possible to guide the arrangement of the interconnector and improve the carrier collection efficiency.

1. A solar cell, comprising:
a semiconductor substrate having a main region and an edge region;
a plurality of finger electrodes provided on any one of a front surface and a rear surface of the substrate and arranged in the main region so as to be spaced apart in parallel; and
a plurality of edge collecting electrodes provided in the edge region,
wherein the edge region is provided at one end side or both end sides of the substrate,
an arrangement direction of the plurality of edge collecting electrodes differs from an arrangement direction of the plurality of finger electrodes, and
the plurality of edge collecting electrodes are connected to at least one finger electrode selected from the plurality of finger electrodes.

2. The solar cell according to claim 1,
wherein the selected at least one finger electrode is selected from three finger electrodes located at an outermost side of the main region.

3. The solar cell according to claim 1,
wherein the plurality of edge collecting electrodes are arranged orthogonal to the plurality of finger electrodes.

4. The solar cell according to claim 1,
wherein an interconnector configured to electrically connect neighboring solar cells is disposed between the edge collecting electrodes.

5. The solar cell according to claim 1,
wherein among the plurality of edge collecting electrodes, an edge collecting electrode located at an edge portion of the solar cell has a different length from edge collecting electrodes located in other regions.

6. The solar cell according to claim 1, further comprising a bus bar electrode,
wherein the bus bar electrode is arranged in a direction crossing the finger electrode, is connected to the finger electrode and is connected to an interconnector that electrically connects neighboring solar cells.

7. The solar cell according to claim 1, further comprising a plurality of conductive pads,
wherein the plurality of conductive pads are arranged in a direction crossing the finger electrode so as to be spaced apart from each other and are connected to an interconnector that electrically connects neighboring solar cells.

8. The solar cell according to claim 1, further comprising a bus bar electrode and a conductive pad,
wherein the bus bar electrode is arranged in a direction crossing the finger electrode and is connected to the finger electrode, and
the plurality of conductive pads are arranged in a direction crossing the finger electrode so as to be spaced apart from each other and are connected to an interconnector that electrically connects neighboring solar cells.

9. The solar cell according to claim 1, further comprising a bus bar electrode and a plurality of conductive pads,
wherein the plurality of conductive pads are arranged so as to be spaced apart from each other on a finger electrode in a region where an interconnector for electrically connecting neighboring solar cells is disposed, and
the bus bar electrode is provided between the plurality of conductive pads.

10. The solar cell according to claim 1,
wherein at least one of the plurality of edge collecting electrodes is connected to a conductive pad located at an outermost side of the main region.

11. The solar cell according to claim 7,
wherein the interconnector is a ribbon-type interconnector or a wire-type interconnector.

12. A solar cell module, comprising:
a first solar cell and a second solar cell arranged adjacent to each other; and
an interconnector configured to electrically connect the first solar cell and the second solar cell,
wherein the first solar cell or second solar cell includes:
a semiconductor substrate having a main region and an edge region;
a plurality of finger electrodes provided to any one of a front surface and a rear surface of the substrate and arranged in the main region so as to be spaced apart in parallel; and
a plurality of edge collecting electrodes provided in the edge region,
wherein the edge region is provided at one end side or both end sides of the substrate,
an arrangement direction of the plurality of edge collecting electrodes differs from an arrangement direction of the plurality of finger electrodes, and
the plurality of edge collecting electrodes are connected to at least one finger electrode selected from the plurality of finger electrodes.

13. The solar cell according to claim 9,
wherein the interconnector is a ribbon-type interconnector or a wire-type interconnector.
